(19) United States
(12) Patent Application Publication
(10) Pub. No.: US 2010/0099266 A1
(43) Pub. Date: Apr. 22, 2010

(54) ETCH REACTOR SUITABLE FOR ETCHING HIGH ASPECT RATIO FEATURES

(75) Inventors: Manfred Oswald, Tharandt (DE); Jivko Dinev, Santa Clara, CA (US); Jan Rupf, Dresden (DE); Markus Meye, Dresden (DE); Francesco Maletta, Radebeul (IT); Uwe Leucke, Dresden (DE); Ron Tilger, Dresden (DE); Farid Abooameri, Pleasanton, CA (US); Alexander Matyushkin, San Jose, CA (US); Denis Koosau, Hayward, CA (US); Xiaoping Zhou, San Jose, CA (US); Thorsten Lehmann, Dohna (DE); Declan Scanlan, Sunnyvale, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/563,526

(22) Filed: Sep. 21, 2009

Related U.S. Application Data
(60) Provisional application No. 61/099,079, filed on Sep. 22, 2008.

(51) Int. Cl. H01L 21/3065; C23F 1/08

(52) U.S. Cl. 438/719; 156/345.24; 257/E21.218

(57) ABSTRACT

Embodiments of the invention provide a method and apparatus that enables plasma etching of high aspect ratio features. In one embodiment, a method for etching is provided that includes providing a substrate having a patterned mask disposed on a silicon layer in an etch reactor, providing a gas mixture of the reactor, maintaining a plasma formed from the gas mixture, wherein bias power and RF power provided the reactor are pulsed, and etching the silicon layer in the presence of the plasma.

### CROSS-REFERENCE TO RELATED APPLICATIONS

This application claims benefit of U.S. Provisional Application Ser. No. 61/099,079 filed Sep. 22, 2008 (Attorney Docket No. APPM/12969L), which is incorporated by reference in its entirety.

### BACKGROUND

1. Field

Embodiments of the invention generally relate to a vacuum processing chamber for etching high aspect ratio features in semiconductor substrates and the like, and the components utilized therein.

2. Description of the Related Art

The demand for faster, more powerful integrated circuits (IC) devices has introduced new challenges for IC fabrication technology, including the need to etch high aspect ratio of features such as trenches or vias on a substrate such as a semiconductor wafer. For example, deep trench storage structures used in some dynamic random access memory applications require deep high aspect ratio trenches etched into a semiconductor substrate. Deep silicone trench etching is typically carried out in a reactive ion etching (RIE) process utilizing silicon oxide mask.

One conventional system which has shown robust performance in etching high aspect ratio features is the CENTURA HART™ Etch System, available from Applied Materials, inc. located in Santa Clara, Calif. The HART™ etching system utilizes a MERIE reactor capable of etching trenches having aspect ratios up to 70:1 while maintaining trench depth uniformity of 5 percent from center to edge. However, in order to enable fabrication of integrated circuits having sub-90 nm critical dimensions, circuit designers have demanded improved uniformity trench uniformity at event high aspect ratios. Thus, it would be desirable to improve etching performance to enable the realization of next generation devices.

Therefore, there is a need for an improved apparatus for etching high aspect ratio features.

### SUMMARY

Embodiments of the invention provide a method and apparatus that enables plasma etching of high aspect ratio features. In one embodiment, an apparatus for plasma etching is provided. The processing chamber includes a chamber body having an interior volume, a showerhead assembly coupled to a ceiling of the chamber body, the showerhead assembly configured to deliver a gas mixture from at least two isolated locations into the chamber body, a substrate support assembly disposed in the chamber body, at least two RF power sources coupled to the substrate support assembly, a bias power source coupled to the substrate support assembly, and a controller interfaced with instructions stored in a memory, the instructions, when executed by the controller, causes a method to be preformed in the processing chamber, the method includes providing the gas mixture through the showerhead assembly into the chamber body, applying RF power to maintain a plasma in the chamber body formed from the gas mixture, applying bias power to the substrate support assembly, wherein the bias power and the RF power applied are pulsed, and etching a silicon layer selectively to a patterned mask to form features in the silicon layer in the presence of the plasma.

In another embodiment, a method for etching high aspect ratio features includes providing a substrate having a patterned mask disposed on a silicon layer in an etch reactor, providing a gas mixture of the etch reactor, applying RF source power to maintain a plasma in the etch reactor formed from the gas mixture, wherein the RF source power has a frequency greater than 1 MHz, applying bias power to the substrate, wherein the bias power has a frequency greater than 50 MHz and the bias power and the RF power provided the etch reactor are pulsed, and etching the silicon layer to form features in the silicon layer in the presence of the plasma.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a sectional view of one embodiment of a processing chamber of the present invention;

FIG. 2 is a schematic diagram illustrating one embodiment of the routing and control of gases delivered from a gas panel to the processing chamber; and

FIG. 3 is a flow diagram of one embodiment of an etching process that may be performed in the processing chamber of FIG. 1.

To facilitate understanding, identical reference numerals have been used, wherever possible, to designate identical elements that are common to the figures. It is contemplated that elements of one embodiment may be advantageously utilized in other embodiments without further recitation.

### DETAILED DESCRIPTION

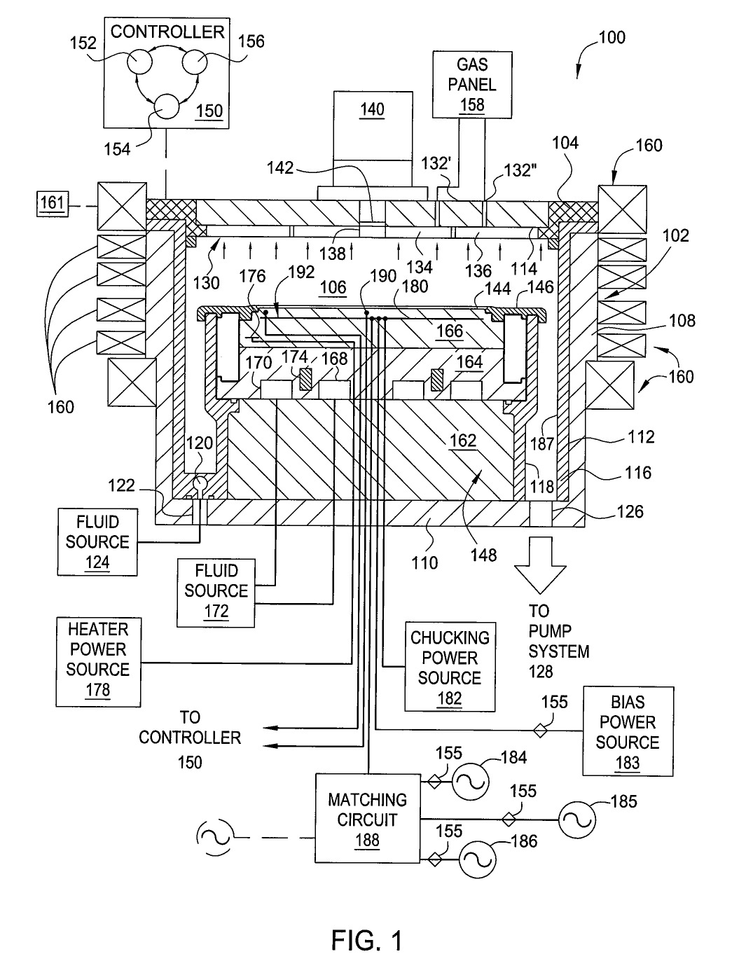

FIG. 1 is a sectional view of one embodiment of an etch reactor 100 suitable for etching high aspect ratio features in a substrate 144. Although the etch reactor 100 is shown including a plurality of features that enable superior etching performance, it is contemplated that other processing chambers may be adapted to benefit from one or more of the inventive features disclosed herein.

The etch reactor 100 includes a chamber body 102 and a lid 104 which enclose an interior volume 106. The chamber body 102 is typically fabricated from aluminum, stainless steel or other suitable material. The chamber body 102 generally includes sidewalls 108 and a bottom 110. A substrate access port (not shown) is generally defined in a sidewall 108 and a selectively sealed by a slit valve to facilitate entry and egress of the substrate 144 from the etch reactor 100. An exhaust port 126 is defined in the chamber body 102 and couples the interior volume 106 to a pump system 128. The pump system 128 generally includes one or more pumps and throttle valves utilized to evacuate and regulate the pressure of the interior volume 106 of the etch reactor 100. In one embodiment, the pump system 128 maintains the pressure inside the interior volume 106 at operating pressures typically between about 10 mTorr to about 20 Torr.

Liners 118, 181 are utilized to protect the sidewall 108 of the chamber body 102. The liners 118, 181 may includes temperature control features, such as resistive heater or channels for cooling fluids. In one embodiment, the cathode liner 118 includes a conduit 120 formed in a flange 121 that supports the liner 118 on the chamber bottom 110. The conduit 120 is fluidly coupled to a fluid source 124 through a passage 122 formed through the bottom 110 of the chamber body 102.

The lid 104 is sealingly supported on the sidewall 108 of the chamber body 102. The lid 104 may be opened to allow excess to the interior volume 106 of the etch reactor 100. The lid 104 includes a window 142 that facilitates optical process monitoring. In one embodiment, the window 142 is comprised of quartz or other suitable material that is transmissive to a signal utilized by an optical monitoring system 140.

The optical monitoring system 140 is positioned to view at least one of the interior volume 106 of the chamber body 102 and/or the substrate 144 positioned on a substrate support assembly 148 through the window 142. In one embodiment, the optical monitoring system 140 is coupled to the lid 104 and facilitates an integrated etch process that uses optical metrology to provide information that enables process adjustment to compensate for incoming pattern inconsistencies (such as CD, thickness, and the like), provide process state monitoring (such as plasma monitoring, temperature monitoring, and the like), and/or end point detection, among others. One optical monitoring system that may be adapted to benefit from the invention is the EyeD® full-spectrum, interferometric metrology module, available from Applied Materials, Inc., of Santa Clara, Calif.

In one embodiment, the optical monitoring system 140 is capable of measuring CDs, film thickness and plasma attributes. The optical monitoring system 140 may use one of more non-destructive optical measuring techniques, such as spectroscopy, interferometry, scatterometry, reflectometry, and the like. The optical monitoring system 140 may be, for example, configured to perform an interferometric monitoring technique (e.g., counting interference fringes in the time domain, measuring position of the fringes in the frequency domain, and the like) to measure the etch depth profile of the structure being formed on the substrate 144 in real time. Details of how to use examples of an optical monitoring have been disclosed in commonly assigned U.S. APPLICATION Ser. No. 60/479,601, titled “Method and System for Monitoring an Etch Process”, filed on Jun. 18, 2003, U.S. Pat. No. 6,413,837, titled “Film Thickness Control Using Spectral Interferometry”, issued on Jul. 2, 2002, and U.S. Application Ser. No. 60/462,493, titled “Process Control Enhancement and Fault Detection Using In-Situ and Ex-situ Metrologies and Data Retrieval In Multiple Pass Wafer Processing”, filed on Apr. 11, 2003.

A gas panel 158 is coupled to the etch reactor 100 to provide process and/or cleaning gases to the interior volume 106. In the embodiment depicted in FIG. 1, inlet ports 132′, 132″ are provided in the lid 104 to allow gases to be delivered from the gas panel 158 to the interior volume 106 of the etch reactor 100. Gases delivered to each inlet port 132′, 132″ from the gas panel 158 may be individually controlled, for example, a first gas mixture may be provided to the inlet port 132′ while a second gas mixture may be provided to the inlet port 132″.

The gas panel 158 may include one or more a vapor delivery apparatuses for the addition of specialty vapors to the etch gas mixture. The amount and type of specialty vapors may be selected to enhance silicon sidewall passivation.

A showerhead assembly 130 is coupled to an interior surface 114 of the lid 104. The showerhead assembly 130 includes a plurality of apertures that allow the gases flowing through the showerhead assembly 130 from the inlet ports 132′, 132″ into the interior volume 106 of the etch reactor 100 in a predefined distribution across the surface of the substrate 144 being processed in the reactor 100.

The showerhead assembly 130 additionally includes a region transmissive to an optical metrology signal. The optically transmissive region or passage 138 is suitable for allowing the optical monitoring system 140 to view the interior volume 106 and/or substrate 144 positioned on the substrate support assembly 148. The passage 138 may be a material, an aperture or plurality of apertures formed or disposed in the showerhead assembly 130 that is substantially transmissive to the wavelengths of energy generated by, and reflected back to, the optical measuring system 140. In one embodiment, the passage 138 includes a window 142 to prevent gas leakage that the passage 138. The window 142 may be a sapphire plate, quartz plate or other suitable material. The window 142 may alternatively be disposed in the lid 104.

In one embodiment, the showerhead assembly 130 is configured with a plurality of zones that allow for separate control of gas flowing into the interior volume 106 of the etch reactor 100. In the embodiment FIG. 1, the showerhead assembly 130 as an inner zone 134 and an outer zone 136 that are separately coupled to the gas panel 158 through the separate inlet ports 132′ 132″. Gases are provided to separate plenums within the showerhead assembly through respective ports 132′, 132″ from the gas panel 158, thereby allowing the gases to be individually controlled in each zone 134, 136 extending into the interior volume 106 of the reactor 100 from the showerhead assembly 130.

The bottom surface of the showerhead assembly 130 generally faces the processing area, and as such, may be coated with a protective material, such as Y₂O₃ or other yttrium containing material. The inner outer diameter of the showerhead assembly 130 may also be coated with a protective material, such as Y₂O₃ or other yttrium containing material.

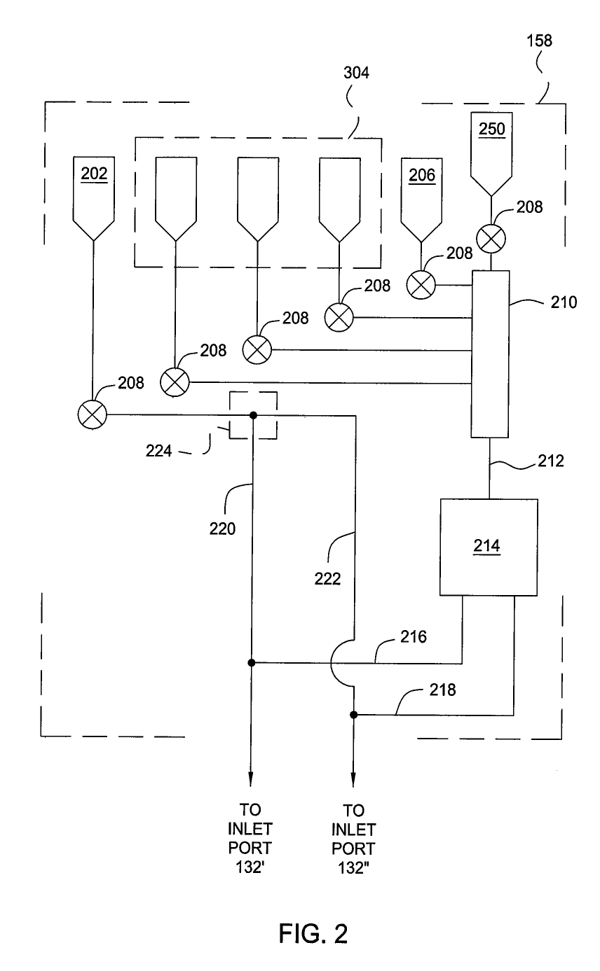

FIG. 2 is one embodiment of a schematic diagram illustrating the routing and control of gases delivered from the gas panel 158 to the etch reactor 100. The gas panel 158 generally includes a plurality of gas sources coupled to a mixing manifold 210 and a flow controller 214.

Generally, flow from each of the gas sources is controlled by a control valve 208. The control valve 208 controls at least one of the flow, rate, pressure, and the like of the fluids provided from the sources. The control valve 208 may include more than one valve, regulator and/or other flow control device.

In the one embodiment, the gas panel 158 includes at least one direct gas source 202, at least one processing gas source 204, at least one carrier gas source 206 and optionally at least one specialty vapor source 250. The processing gas sources 204 and the carrier gas source 206 are fluidly coupled to the mixing manifold 210 by individual gas lines. The various gases and/or vapors from the sources 204, 206, 250 are combined in the mixing manifold 210 into pre-delivery gas mixture. As such, the composition of the pre-delivery gas mixture in the mixing manifold 210 may be chosen by selectively opening the respective valves 208 so that a predetermined combination of specially vapor, carrier and process gases are combined. For example, at least one processing gas from the processing gas source 204, and optionally at least one carrier gas from the carrier gas source 206 may be combined in the mixing manifold 210 in any combination. Optionally, specialty vapors form the source 250 may also be provided to the mixing manifold 210. Examples of processing gases include SiCl₄, HBr, NF₃, O₂ and SiF₄, among others. Examples of carrier gases include N2, He, Ar, other gases inert to the process and non-reactive gases. Examples of specialty vapors that may be utilized include, but are not limited to, TiCl4. Such vapor additions can be utilized to add suitable material to reinforce the sidewall passivation during etching. Thus, a better profile control can be obtained and superior anisotropy of etching is achieved. In general, the idea of such additional vapor or gas is to provide species which are capable of enhancing the sidewall passivation in order to improve CD control. Typical sidewall passivation is a mixture of silicon oxide in various stoichiometries. The titanium in this case forms titaniumoxide which is integrated into the passivation layer. Methane (CH4) can also be added for controlling sidewall passivation. The addition of carbon forms SiC (siliconcarbide) which gives very etch resistant material properties.

The flow controller 214 is coupled to the mixing manifold 210 by a primary gas feed 212. The flow controller 214 is configured to split the pre-delivery gas mixture flowing from the mixing manifold 210 into sub-mixtures delivered to the reactor 100 through separate gas feed lines. Generally, the number of gas feed lines is commensurate with the number of zones (or isolated plenums) defined in the showerhead assembly 130. In the embodiment depicted in FIG. 2, two gas feed lines 216, 218 couple the flow controller 214 to the respective inlet ports 132′, 132″.

The flow controller 214 is generally configured to control the ratio of sub-mixtures flowing in each feed line 216, 218. In this manner, the ratio of gas sub-mixtures flowing to each zone, and ultimately to each region of the substrate 144, may be controlled. The flow controller 214 may split the pre-delivery gas mixture using electronic or mechanical devices. In one embodiment, the flow controller 214 is able to dynamically control the ratio in response to a signal from the controller 150, thereby enabling the ratio to be changed between batches of substrates, between substrates, and/or in-situ processing a single substrate. In another embodiment, the flow controller 214 is set such that the ratio is fixed between the lines 216, 218. The ratio may be set by one or more orifices disposed in the flow controller 214 such that the flow from the primary gas feed 212 is preferentially split between the gas feed lines 216, 218.

In one embodiment, the flow controller 214 provides more gas to the inner zone 134 than the outer zone 136. In still another embodiment, the flow controller 214 provides more gas to the outer zone 136 than the inner zone 134. In still another embodiment, the flow controller 214 provides more gas to the inner zone 134 than the outer zone 136 for a first period of substrate processing, then changes the ratio in-situ processing the substrate to provide more gas to the outer zone 136 than the inner zone 134 for a second period of substrate processing. It is contemplated that the flow controller 214 may be configured to control the ratio between flows delivered to different zones in the etch reactor 100 in other sequences or ratios.

A directly injected gas is also provided to the interior volume 106 of the etch reactor 100 from the direct injection gas source 202 of the gas panel 158. The amount of directly injected gas flowing from the direct injection gas source 202 is controlled by a valve 208.

In one embodiment, the directly injected gas is provided to at least one of the gas feeds 216, 218. In another embodiment, the directly injected gas is teed into two direct feed lines 220, 222 that are respectively teed into the gas feed lines 216, 218. In yet another embodiment, the directly injected gas is provided to at least one of the gas feeds coupled to the inlet ports 132′, 132″. In still another embodiment, the directly injected gas is provided to at least one of the plenums of the showerhead assembly 130.

In the embodiment depicted in FIG. 2, the same amount of directly injected gas is provided to each zone 134, 136. Optionally, a second flow controller 224 (shown in phantom, and similar to the flow controller 214) may be utilized to provide different ratios of directly injected gas to each of the zones 134, 136.

Returning to FIG. 1, a substrate support assembly 148 is disposed in the interior volume 106 of the etch reactor 100 below the showerhead assembly 130. The substrate support assembly 148 holds the substrate 144 during processing. The substrate support assembly 148 generally includes a plurality of lift pins (not shown) disposed therethrough that are configured to lift the substrate from the support assembly 148 and facilitate exchange of the substrate 144 with a robot (not shown) in a conventional manner.

In one embodiment, the substrate support assembly 148 includes a mounting plate 162, a base 164 and an electrostatic chuck 166. The mounting plate 162 is coupled to the bottom 110 of the chamber body 102 includes passages for routing utilities, such as fluids, power lines and sensor leads, among other, to the base 164 and chuck 166.

At least one of the base 164 or chuck 166 may include at least one optional embedded heater 176, at least one optional embedded isolator 174 and a plurality of conduits to control the lateral temperature profile of the support assembly 148. In the embodiment depicted in FIG. 1, one annular isolator 174 and two conduits 168, 170 are disposed in the base 164, while a resistive heater 176 is disposed in the chuck 166. The conduits are fluidly coupled to a fluid source 172 that circulates a temperature regulating fluid therethrough. The heater 176 is regulated by a power source 178. The conduits 168, 170 and heater 176 are utilized to control the temperature of the base 164, thereby heating and/or cooling the electrostatic chuck 166, thereby controlling, at least in part, the temperature of the substrate 144 disposed on the electrostatic chuck 166.

The two separate cooling conduits 168, 170 formed in the base 164 define at least two independently controllable temperature zones. It is contemplated that additional cooling passages and/or the layout of the passages may be arranged to define additional temperature control zones. In one embodiment, the first cooling conduit 168 is arranged radially inward of the second cooling conduit 170 such that the temperature control zones are concentric. It is contemplated that the conduits 168, 170 may radially orientated, or have other geometric configurations. The cooling conduits 168, 170 may be coupled to a single source 172 of a temperature controlled heat transfer fluid, or may be respectively coupled to a separate heat transfer fluid source.

The isolator 174 is formed from a material having a different coefficient of thermal conductivity than the material of the adjacent regions of the base 164. In one embodiment, the isolator 174 has a smaller coefficient of thermal conductivity than the base 164. In a further embodiment, the isolator 174 may be formed from a material having an anisotropic (i.e. direction-dependent) coefficient of thermal conductivity. The isolator 174 functions to locally change the rate of heat transfer between the support assembly 148 through the base 164 to the conduits 168, 170 relative to the rate of heat transfer though neighboring portions of the base 164 not having an isolator in the heat transfer path. An isolator 174 is laterally disposed between the first and second cooling conduits 168, 170 to provide enhanced thermal isolation between the temperature control zones defined through the substrate support assembly 148.

In the embodiment depicted in FIG. 1, the isolator 174 is disposed between the conduits 168, 170, thereby hindering lateral heat transfer and promoting lateral temperature control zones across the substrate support assembly 148. Thus, by controlling the number, shape, size, position and coefficient of heat transfer of the inserts, the temperature profile of the electrostatic chuck 166, and the substrate 144 seated thereon, may be controlled. Although the isolator 174 is depicted in FIG. 1 shaped as an annular ring, the shape of the isolator 174 may take any number of forms.

The temperature of the electrostatic chuck 166 and the base 164 is monitored using a plurality of sensors. In the embodiment depicted in FIG. 1, a first temperature sensor 190 and a second temperature sensor 192 are shown in a radially spaced orientation such that the first temperature sensor 190 may provide the controller 150 with a metric indicative of the temperature of a center region of the support assembly 148 while the second temperature sensor 192 provide the controller 150 with a metric indicative of the temperature of a perimeter region of the support assembly 148.

The electrostatic chuck 166 is disposed on the base 164 and is circumscribed by a cover ring 146. The electrostatic chuck 166 may be fabricated from aluminum, ceramic or other materials suitable for supporting the substrate 144 during processing. In one embodiment, the electrostatic chuck 166 is ceramic. Alternatively, the electrostatic chuck 166 may be replaced by a vacuum chuck, mechanical chuck, or other suitable substrate support.

The electrostatic chuck 166 is generally formed from ceramic or similar dielectric material and comprises at least one electrode 180. The electrode 180 is coupled to a chucking power source 182 which is utilized to control the chucking force applied to the substrate disposed on the substrate support assembly 148.

A bias power source 183 is coupled to the electrode 180 or other electrode within the substrate support assembly 148. The bias power source 183 provides a bias to the electrode 180 which causes ions in the plasma to accelerate towards the substrate during etching. The bias power source 183 may be configured to provide either DC or RF bias power. In one embodiment, the bias power source 183 provides power between 500 and 7000 Watts, such as between about 700 Watts and about 4000 Watts, at frequency between about 2 kHz and about 100 MHz. In one embodiment, the bias power frequency is controlled at about 1 kHz and about 100 MHz, such as about 2 kHz, 100 MHz or 60 MHz. The bias power provided by the bias power source 183 may be pulsed or applied continuously.

The electrode 180 (or other electrode disposed in the chuck 166 or base 164) may further be coupled to one or more RF power sources for forming and maintaining a plasma by ionizing the gases introduced into the etch reactor 100. In the embodiment depicted in FIG. 1, the electrode 180 is coupled, through a matching network 188, to a first RF power source 184, a second RF power source 185 and a third RF power source 186. The sources 184, 185, 186 are generally capable of producing an RF signal having a frequency from about 50 kHz to about 3 GHz and a power of up to about 11,000 Watts. In one example, the source power is controlled at between about 6 Watts and about 11,000 Watts, for example, about 300 Watts and about 11,000 Watts at a frequency about 2 MHz. The matching network 188 matches the impedance of the sources 184, 185, 186 to the plasma impedance. A single feed couples energy from both sources 184, 185, 186 to the electrode 180. Alternatively, each source 184, 185, 186 can be coupled to the electrode 180 via a separate feed. Filters 155 may be used to protect the sources 184, 185, 186 from power generated by the other sources. Multiple RF frequencies coupled to the plasma through the cathode is used to tailor ion energy distribution for enhanced Si etch rate and enhanced selectivity. One or more of the RF power sources 184, 185, 186 may be alternatively coupled to the showerhead assembly 130.

In one embodiment, the sources 184, 185, 186 may operate in pulsing mode to enhance ion energy distribution function and plasma density distribution for enhanced Si etch rate and enhanced selectivity. Pulsing may be made available either internally triggered within the power sources, or externally synchronized using the controller by opening and closing one or more switches disposed between the RF power sources and the electrode 180.

The electrostatic chuck 166 may also include at least one embedded heater 176 controlled by a power supply 178. In one embodiment, the heater 176 may be operated to maintain the temperature of the surfaces of electrostatic chuck 166 that are exposed to the processing environment at up to about 120 degrees Celsius or higher.

The electrostatic chuck 166 may further comprise a plurality of gas passages (not shown), such as grooves, that are formed in a substrate supporting surface of the chuck and fluidly coupled to a source of a heat transfer (or backside) gas. In operation, the backside gas (e.g., helium (He)) is provided at controlled pressure into the gas passages to enhance the heat transfer between the electrostatic chuck 166 and the substrate 144. Conventionally, at least the substrate supporting surface of the electrostatic chuck is provided with a coating resistant to the chemistries and temperatures used during processing the substrates.

A plurality of magnetic coils 160 may be disposed around the exterior of the chamber body 102. In one embodiment, up to 8 or more magnetic coils 160 may be utilized to tailor the plasma distribution within the etch reactor 100. In the embodiment depicted in FIG. 1, six magnetic coils 160 are shown. The magnetic coils 160 may be independently controlled to optimize magnetic field uniformity within the etch reactor 100. The magnetic coils 160 are coupled to at least one power source 161 such that the magnetic field generated by each magnetic coil 160 may be independently controlled. Although only one power source 161 is shown in FIG. 1, each magnetic coil 160 may be coupled to an individual and dedicated power source 161. Alternatively, the magnetic coils 160 may share one or more power sources 161.

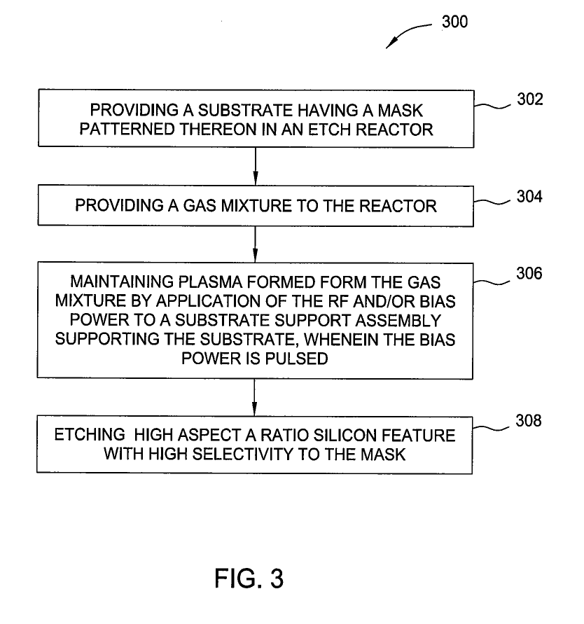

FIG. 3 is flow diagram illustrating one embodiment of a method that can be practiced in the etch reactor 100 or other suitable etch reactor. The method 300 begins at act 302 by providing a substrate having a mask patterned thereon in an etch reactor, such as the reactor 100 or other suitable reactor. At act 304, a gas mixture is provided to the reactor. In one embodiment, the gas mixture includes HBr. One or more of specialty vapors, NF₃, Ar, O₂, and SiCl₄ may be included in the gas mixture at various times. For example, NF₃ and/or O₂ may be periodically added to remove passivation material from the sidewalls of the feature being formed. At act 306, a plasma, formed form the gas mixture, is maintained. The plasma may be maintained by application of the RF and/or bias power to the substrate support assembly 148. The power, frequency, timing and duty cycle of the RF and/or bias power may be selected as described below. At act 308, a high aspect ratio silicon feature is etched with high selectivity to the mask in the presence of the plasma.

The substrate provided at act 302 can include a silicon layer. The silicon layer is covered with a patterned mask, such as a photoresist mask and/or hardmask. The hardmask material can be any kind of silicondioxide or siliconnitride or any other suitable material with ceramic material properties, for example, zirconiumoxide, aluminumoxide, aluminumnitride, titanoxide or combinations of such materials in stacked layers.

The plasma, formed from the gases provided through the multiple gas flow zones of the showerhead assembly, may be maintained at act 304 by the application of about 500 to about 2800 W to the substrate support assembly by the one or more RF sources 184, 185, 186. In one embodiment, the power is applied at 60 MHz. The method may include regulating the chamber pressure between about 0 to about 300 milliTorr (mT). The substrate may be biased with about 500 to about 2800 Watts (W) of bias power. In one embodiment, the bias power is applied at a frequency of about 2 MegaHertz (MHz). The bias power may be pulsed at a duty cycle between about 20 percent and about 98 percent, such as about 35 percent and about 95 percent. A magnetic B-field is applied across the chamber using the magnetic coils 160 having between about 0 and about 140 Gauss (G). The silicon material on the substrate is plasma etched through the openings in the mask to form a trench having an aspect ratio up to at least 80:1.

A mixture of process, direct injection, specialty vapor and/or inert gases are provided to the chamber for plasma etching. The mixture may include at least one of HBr, NF₃, O₂, SiF₄, SiCl₄ and Ar. In one embodiment, the process gases provided to the mixing manifold include HBr and NF₃, while O₂, SiF₄ and SiCl₄ may optionally be provided. In an exemplary embodiment, between about 50 to about 500 sccm of HBr, between about 0 to about 200 sccm of NF₃, between about 0 to about 200 sccm of O₂, between about 0 to about 200 sccm of SiF₄, between about 0 to about 300 sccm of SiCl₄, and between about 0 to about 400 sccm of Ar are provided to the mixing manifold for a process suitable for etching silicon material on a 300 mm substrate. The mixed gases are provided to the plenums at a flow ratio selected commensurate with the feature density, size and lateral location. SiCl₄ may be used as a direct injection gas provided to the plenums of the showerhead assembly bypassing the mixing manifold.

The power provided to the substrate support assembly 148 by the one or more RF sources 184, 185, 186 may be pulsed. Pulsing of the RF source power and/or bias power applied to the substrate support assembly 148 beneficially increases the selectivity of the etch process of silicon over the mask. Furthermore, the pulsed RF source power and/or RF bias power allows higher RF frequencies to be employed, which results in higher etch rates at the center of the substrate. In one embodiment, the RF source power is controlled at greater than 1 MHz, such as about 2 MHz, and the RF bias power is controlled greater than about 50 MHz, such as about 100 MHz, which may improve both etching selectivity and etched film uniformity. Thus, pulsed RF allows the frequency process window to widen, thereby allowing frequency to be used to tune the center to edge etching rate for more uniform etch depth processing results.

The power applied to the substrate support assembly 148 by the RF and/or bias sources may be pulsed either by the sources or external switch (shown as 155 in FIG. 1). The timing of the pulses provided by the bias and RF power sources may be controlled through a number of techniques. In the following examples, the RF source is utilized to provide a time reference for the application of power to the bias source, and as such, the RF source is referred to for convenience as a master and the bias source as a slave. It is contemplated that the bias source may be used as the master. In one embodiment, the timing of the power pulses provided by the slave is synchronized to the master. The master/slave may have duty cycle timing that is fully synchronized, meaning that when the master is providing power, the slave is providing power, and when the master is not providing power, the slave is not providing power. In another embodiment, master/slave may have duty cycle timing that is inverted, meaning when the master is providing power, the slave is not providing power, and when the master is providing power, the slave is not providing power. In yet another embodiment, master/slave may have duty cycle timing that is shifted, meaning that the slave power providing state is shifted or staggered (lagging in time) relative to the power providing state of the master. A shifted duty cycle timing may result in the slave providing power only during a portion of the time that the master is providing power, the slave providing power only during a portion of the time that the master is not providing power, or the slave providing power during a portion of the time that includes a portion of the time that the master is providing power and a portion of the time that the master is not providing power.

Process results have demonstrated that low bias power duty cycles, i.e., shorter bias pulse on to off times, improve mask to silicon selectivity. Low duty cycle is defined as less than about 50 percent on for each pulse. Increased choking (e.g., dosing of the etched trench by passivation materials or etch by-product) of the etched feature at low bias power duty cycles may be offset by increasing the frequency of the bias power, thereby enabling improvements in etch depth uniformity. Increasing the frequency of the bias power also increases the etch rate. Additionally, pulsing the bias power allows for higher RF power to be utilized, resulting in faster etch rates without loss of mask selectivity. Additionally, shifted duty cycle timing also demonstrated a reduction in the amount of choking during the etch process as compared to a synchronized timing with similar process parameters.

Thus, utilizing frequency and duty cycle of the bias power, along with timing of the application of bias power allows a wide process window that enables edge to center etch depth uniformity control with high mask to silicon etch required to successfully etch high aspect ratio features in silicon. Etch depth uniformity was improved for all duty cycles and timing at higher bias power frequencies. Higher bias power frequencies also produced faster etching at the edge of the substrate. Selectivity was maximized at higher bias power frequencies with low duty cycles. Reduction in the RF power applied at low duty cycles also improves etch depth uniformity, at the expense of etch rate.

It has been demonstrated that the processing chamber and methods described above enables etching high aspect ratio features with good uniformity across the surface of the substrate and high mask to silicon selectivity.

While the foregoing is directed to embodiments of the present invention, other and further embodiments of the invention may be devised without departing from the basic scope thereof, and the scope thereof is determined by the claims that follow.

What is claimed is:

1. A processing chamber comprising:
a chamber body having an interior volume;
a showerhead assembly coupled to a ceiling of the chamber body, the showerhead assembly configured to deliver a gas mixture from at least two isolated locations into the chamber body;
a substrate support assembly disposed in the chamber body;
at least two RF power sources coupled to the substrate support assembly;
a bias power source coupled to the substrate support assembly; and
a controller interfaced with instructions stored in a memory, the instructions, when executed by the controller, causes a method to be preformed in the processing chamber, the method comprising:
providing the gas mixture through the showerhead assembly into the chamber body;
applying RF power from the RF power source to maintain a plasma in the chamber body formed from the gas mixture;
applying bias power from the bias power source to the substrate support assembly, wherein the bias power and the RF power applied are pulsed; and
etching a silicon layer selectively to a patterned mask to form features in the silicon layer in the presence of the plasma.

2. The processing chamber of claim 1, wherein the instructions further cause the method to comprise:
pulsing the RF bias power at a duty cycle between about 35 percent and about 95 percent.

3. The processing chamber of claim 1, further comprising:
at least one filter disposed between the RF power source and the substrate support assembly.

4. The processing chamber of claim 1, further comprising:
a third RF power source coupled to the substrate support assembly.

5. The processing chamber of claim 1, wherein the instructions further cause the method to comprise:
providing processing gases with different flow rate from each of the isolated locations formed in the showerhead assembly.

6. The processing chamber of claim 1, wherein the RF power sources are configured to generate power at a frequency greater than about 1 MHz.

7. The processing chamber of clam 1, wherein the bias power source is configured to generate power at a frequency greater than about 50 MHz.

8. The processing chamber of claim 1, wherein the bias power source is configured to generate power at a frequency about 100 MHz.

9. The processing chamber of claim 1, further comprising:
a plurality of magnetic coils disposed around an exterior of the chamber body.

10. The processing chamber of claim 9, wherein up to 8 or more magnetic coils are disposed around the exterior of the chamber body.

11. The processing chamber of claim 1, further comprising:
sources of HBr, NF₃, Ar, O₂ and SiCl₄ coupled to the chamber body.

12. The processing chamber of claim 1, wherein the instructions further cause the method to comprise:
removing passivation material from sidewall of the features being formed in the silicon layer by supplying a NF₃ gas during etching.

13. A method for etching high aspect ratio features, comprising:
providing a substrate having a patterned mask disposed on a silicon layer in an etch reactor;
providing a gas mixture of the etch reactor;
applying RF source power to maintain a plasma in the etch reactor formed from the gas mixture, wherein the RF source power has a frequency greater than 1 MHz;
applying bias power to the substrate, wherein the bias power has a frequency greater than 50 MHz and the bias power and the RF power provided the etch reactor are pulsed; and
etching the silicon layer to form features in the silicon layer in the presence of the plasma.

14. The method of claim 13, wherein applying RF source power further comprises:
applying power from up to three RF power source through a substrate support assembly disposed in the etch reactor.

15. The method of claim 13, wherein applying the bias power to the substrate through a substrate support assembly disposed in the etch reactor.

16. The method of claim 13, wherein applying the bias power to the substrate further comprises:
pulsing the RF bias power at a duty cycle between about 35 percent and about 95 percent.

17. The method of claim 13, wherein providing the gas mixture further comprises:
providing the gas mixture selected from a group consisting of HBr, NF₃, Ar, O₂ and SiCl₄.

18. The method of claim 13, wherein etching the silicon layer further comprises:
removing passivation material from sidewall of the features being formed in the silicon layer by supplying a NF₃ gas during etching.

19. A processing chamber comprising:
a chamber body having an interior volume;
a showerhead assembly coupled to a ceiling of the chamber body, the showerhead assembly configured to deliver a gas mixture from at least two isolated locations into the chamber body;
a substrate support assembly disposed in the chamber body;
at least two RF power sources coupled to the substrate support assembly configured to provide RF power at a frequency greater than 1 MHz;
a bias power source coupled to the substrate support assembly configured to provide RF bias power at a frequency greater than 50 MHz; and
a controller interfaced with instructions stored in a memory, the instructions, when executed by the controller, causes a method to be preformed in the processing chamber, the method comprising:
providing the gas mixture through the showerhead assembly into the chamber body through the two isolated locations of the showerhead assembly, wherein the gas mixture supplied through each of the isolated locations of the showerhead assembly has different flow rates;
applying RF power from the at least two RF sources to the substrate support assembly to maintain a plasma in the chamber body formed from the gas mixture;
applying bias power from the bias power source to the substrate support assembly, wherein the bias power and the RF power applied are pulsed; and
etching a silicon layer selectively to a patterned mask to form features in the silicon layer in the presence of the plasma.

20. The processing chamber of claim 19, wherein the instructions further cause the method to comprise:
pulsing the RF bias power at a duty cycle between about 35 percent and about 95 percent.
